(19) United States
(12) Patent Application Publication
(10) Pub. No.: US 2026/0068606 A1
(43) Pub. Date: Mar. 5, 2026

(54) DETECTION OF STRUCTURAL DEFECTS IN AN INTEGRATED CIRCUIT

(71) Applicant: STMicroelectronics International N.V., Geneva (CH)

(72) Inventor: Laurent Lopez, Peynier (FR)

(21) Appl. No.: 19/303,655

(22) Filed: Aug. 19, 2025

(30) Foreign Application Priority Data
Aug. 28, 2024 (FR) 2409177

(51) Int. Cl. H01L 21/66; G01R 31/28

(52) U.S. Cl. CPC H01L 22/12; G01R 31/2853; G01R 31/2884

(57) ABSTRACT

An electronic system comprising an integrated circuit, including a semiconductor substrate, an interconnection portion located above the substrate and having metal levels and vias and contacts levels embedded in an electrically-insulating region as well as contact pads located at the last metal level of the interconnection portion, and a detection system configured to detect a possible presence of at least one type of structural defects within at least one area of the interconnection portion located at least beneath a contact pad.

### CROSS-REFERENCE TO RELATED APPLICATIONS

This application claims the benefit of French Application No. FR 2409177, filed on Aug. 28, 2024, which application is hereby incorporated herein by reference.

### TECHNICAL FIELD

Embodiments and implementations relate to integrated circuits, in particular the detection of structural defects in these integrated circuits, for example cracks and/or delaminations.

### BACKGROUND

An integrated circuit conventionally includes a part known to a person skilled in the art by the acronym “FEOL” (“Front End Of Line” or more simply “front end”) including the various components, such as transistors, implemented in and on the semiconductor substrate of the integrated circuit, and an interconnection portion known to a person skilled in the art by the acronym “BEOL” (“Back End Of Line” or more simply “back end”) including a network of metal tracks, of vias between the different metal levels and of contacts between the first metal level and the active areas of the substrate and/or of the different components (gate, source and drain portions of the transistors for example) buried in a dielectric material and ensuring in particular an interconnection between the components of the integrated circuit.

### SUMMARY

Integrated circuits are manufactured simultaneously on locations on a silicon wafer separated by cutting lines.

Then, once manufactured, the integrated circuits are individualized by cutting the wafer, typically by sawing, along the cutting lines.

During the operation of sawing the aforementioned wafer, cracks and/or a phenomenon of delamination (i.e. a decohesion of the layers) may occur in the BEOL part, in particular at the periphery of the integrated circuit.

French Patent Application No. 2406877 filed by the Applicant describes a device including in particular an annular wall located at the periphery of the integrated circuit allowing detecting cracks and/or delaminations resulting from the aforementioned sawing operation.

However, there is a constant need to further improve the detection of structural defects in an integrated circuit, in particular cracks and/or delaminations, which could allow moisture to penetrate into the integrated circuit, which is detrimental to the proper operation thereof.

In this respect, the Inventor has observed that such structural defects could also result from the manufacturing process of the integrated circuit itself, and in particular during the steps of soldering connecting wires (“wire bonding”) or of forming soldering balls on the contact pads (“pads”) located at the last metal level of the interconnection portion (BEOL).

Indeed, the Inventor has observed that these steps at these contact pads might locally create cracks and/or peeling of the structure.

According to one aspect, an electronic system is provided comprising an integrated circuit, including a semiconductor substrate, an interconnection portion located above the substrate and having metal levels and vias and contact levels embedded in an electrically-insulating region as well as contact pads located at the last metal level of the interconnection portion, and a detection system configured to detect the possible presence of at least one type of structural defects, for example a crack and/or a delamination, within at least one area of the interconnection portion located at least beneath a contact pad.

According to one embodiment, the detection system comprises an electrically-conductive region located at least in the area and a detection device configured to detect at least one electrical discontinuity of the region.

The detection device may be located within the integrated circuit.

In this respect, it may include, for example, inverters associated with a processing unit, for example an electronic chip present in the integrated circuit.

Alternatively, the detection device may include a module external to the integrated circuit, for example a tester.

According to one variant, it is possible to arrange, beneath the corresponding contact pad, an electrically-conductive track which does not contact the contact pad, which allows, if one wishes so, continuously detecting the apparition of a structural defect beneath the contact pad, even when the integrated circuit is in its application operation.

More specifically, according to an embodiment of this variant, in the case where the interconnection portion includes N metal levels with N greater than or equal to 2, the rank 1 metal level being the metal level the closest to the substrate, the contact pads being located at the rank N metal level, the electrically-conductive region may include an electrically-conductive track having a first end and a second end located at the rank 1 metal level and able to be electrically coupled to the detection device, a first branch extending from the first end up to the rank N−1 metal level, and a second branch extending from the rank N−1 metal level up to the second end, the two branches being mutually connected at the rank N−1 metal level.

For example, each branch may include a stack of metal portions, respectively located at the rank 1 to N−1 metal levels, and of vias between these metal portions, and a connection metal portion located at the rank N−1 metal level connecting the two metal portions of the two branches located at the rank N−1 metal level.

According to another embodiment of this variant, wherein the interconnection portion includes, herein again, N metal levels with N greater than or equal to 2, the rank 1 metal level being the metal level the closest to the substrate, the contact pads being located at the rank N metal level, the electrically-conductive region includes a first active area and a second active area located in the semiconductor substrate as well as an electrically-conductive track.

This electrically-conductive track has a first end and a second end located at the rank 1 metal level and able to be electrically coupled to the detection device, a first contact connected between the first end and the first active area, a first branch extending from the first active area up to the rank N−1 metal level, a second branch extending from the rank N−1 metal level up to the second active area, and a second contact connected between the second active area and the second end, the two branches being mutually connected at the rank N−1 metal level.

Such an embodiment wherein the electrically-conductive track that does not contact the contact pad but which extends up to the active areas of the substrate, allows, if one wishes so, continuously detecting the apparition of a structural defect beneath the contact pad, even when the integrated circuit is in the application operation thereof, and that being so between the rank N−1 metal level and the semiconductor substrate.

For example, each branch may include a stack of metal portions, respectively located at the rank 1 to N−1 metal levels, of vias between these metal portions and of a contact between the corresponding active area and the metal portion located at the rank 1 metal level, and a connection metal portion located at the rank N−1 metal level connecting the two metal portions of the two branches located at the rank N−1 metal level.

The electrically-conductive region may include several electrically-conductive tracks.

These tracks may be individualized and each connected to a respective processing unit, or respectively connected at four input ports of one single processing unit, or connected in a multiplexed manner at one single input port of the processing unit, or connected in series at one single input port of the processing unit.

According to another variant, the electrically-conductive track located beneath the contact pad could contact the latter. This allows also detecting a defect located at the contact pad or just below. However, it is not possible to perform this detection during the application operation of the integrated circuit.

More specifically, in this other variant, the at least one area of the interconnection portion (in which it is possible to detect the possible presence of a structural defect) also incorporates the contact pad.

According to an embodiment of this other variant, wherein the interconnection portion includes N metal levels, the rank 1 metal level being the metal level the closest to the substrate, the contact pads being located at the rank N metal level, the electrically-conductive region includes an electrically-conductive track having a first end located at the contact pad and a second end located at the rank 1 metal level, the two ends being able to be electrically coupled to the detection device, and a branch extending between the first end and the second end.

For example, this branch includes a stack of metal portions, respectively located at the rank 1 to N−1 metal levels, of vias between these metal portions, and of a via between the metal portions located at the N−1 metal level and the contact pad.

According to another embodiment of this other variant, wherein the interconnection portion includes N metal levels, the rank 1 metal level being the metal level the closest to the substrate, the contact pads being located at the rank N metal level, and the electrically-conductive region includes a third active area located in the semiconductor substrate and an electrically-conductive track.

This electrically-conductive track has a first end located at the contact pad and a second end located at the rank 1 metal level, the two ends being able to be electrically coupled to the detection device, a branch extending between the first end and the third active area, and a third contact connected between the third active area and the second end.

This other embodiment allows detecting a defect located at the contact pad or just below or between this contact pad and the substrate. However, herein again, it is possible to perform this detection during the application operation of the integrated circuit

For example, the branch may include a stack of metal portions, respectively located at the 1 to N−1 rank metal levels, of vias between these metal portions, of a via between the metal portion located at the N−1 metal level and the contact pad and of a contact between the third active area and the metal portion located at the rank 1 metal level.

The detection system may include a pull-up resistor having a first terminal able to be coupled to a supply voltage and a second terminal coupled to the second end of the electrically-conductive track.

The detection system may also include a pull-down resistor having a first terminal able to be coupled to a power supply ground point, for example the ground, and a second terminal coupled to the second end of the electrically-conductive track.

The electrically-conductive region may include several star-connected electrically-conductive tracks, the contact pad incorporating the first ends of all tracks.

According to another aspect, an integrated circuit belonging to the electronic system as defined hereinbefore is provided.

According to another aspect, a method is provided, comprising providing an integrated circuit, including a semiconductor substrate, an interconnection portion located above the substrate and having metal levels and vias and contacts levels embedded in an electrically-insulating region as well as contact pads located at the last metal level of the interconnection portion, and detecting the possible presence of at least one type of structural defects, for example a crack and/or a delamination, within at least one area of the interconnection portion located at least beneath a contact pad.

According to one implementation, the detection comprises detecting at least one electrical discontinuity of an electrically-conductive region located at least in the area.

The areas may also incorporate the contact pad.

The electrically-conductive region may include at least one active located in the semiconductor substrate.

### BRIEF DESCRIPTION OF THE DRAWINGS

Other advantages and features of the embodiments will appear upon examining the detailed description of non-limiting modes of implementation and embodiments, and from the appended drawings, wherein:

FIG. 1 illustrates a plan view of an integrated circuit in accordance with an embodiment;

FIG. 2 illustrates a longitudinal section of the integrated circuit in accordance with an embodiment;

FIG. 3 illustrates a longitudinal section of the integrated circuit in accordance with an embodiment;

FIG. 4 illustrates a top view of the contact pad in accordance with an embodiment;

FIG. 5 illustrates a longitudinal section of the integrated circuit in accordance with an embodiment;

FIG. 6 illustrates a detecting system in accordance with an embodiment;

FIG. 7 illustrates a detecting system in accordance with an embodiment;

FIG. 8 illustrates a detecting system in accordance with an embodiment;

FIG. 9 illustrates a top view of the contact pad in accordance with an embodiment;

FIG. 10 illustrates a method of detecting defects in the integrated circuit in accordance with an embodiment;

FIG. 11 illustrates a longitudinal section of the integrated circuit in accordance with an embodiment; and

FIG. 12 illustrates a longitudinal section of the integrated circuit in accordance with an embodiment.

### DETAILED DESCRIPTION OF ILLUSTRATIVE EMBODIMENTS

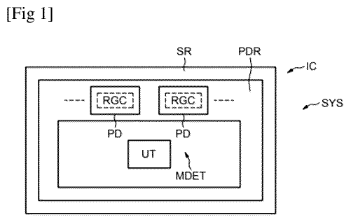

In FIG. 1, the reference SYS designates an electronic system comprising an integrated circuit IC and a detection system MDET.

As it will be seen in more detail hereinafter, the detection system MDET may be located entirely in the integrated circuit IC or partially outside the integrated circuit IC.

This integrated circuit IC includes a ring PDF of contact pads PD (“pads” in English) as well as a peripheral sealing ring SR.

In this example, the integrated circuit IC also includes a processing unit UT, for example an electronic chip which, in some cases, may be part of the detection system MDET.

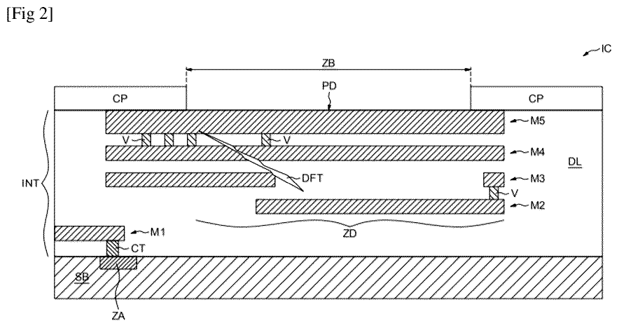

As illustrated in FIG. 2, the integrated circuit comprises a semiconductor substrate SB as well as an interconnection portion INT (known to a person skilled in the art by the acronym “BEOL”: “Back End Of Lines”) located above the substrate SB.

This interconnection portion has metal levels, herein 5 metal levels M1-M5 and vias levels V embedded in an electrically-insulating region DL, generally a dielectric material.

The interconnection portion also has the contact pads PD located at the last metal level of the interconnection portion.

To simplify the figure, only one contact pad PD is shown.

The interconnection portion INT also has a contacts level between the rank 1 metal level M1 and active regions of the substrate and/or components such as transistors.

In FIG. 2, for simplicity, only one contact CT is shown between an active region ZA of the substrate (for example an N⁺ doped region) and a track of the metal level M1.

Still to simplify the figure, the insulating regions, for example of the “shallow trench” type (known to a person skilled in the art by the acronym “STI”: Shallow Trench Isolation”) isolating the active region from the rest of the substrate SB, are not shown.

The interconnection portion INT is conventionally covered with a passivation layer CP having open areas ZB so as to uncover the contact pads PD.

These contact pads are intended to receive, by soldering, connecting wires (“wire bonding”) or solder balls.

These operations of soldering the wires or the balls may cause the apparition of defects DFT in an area ZD located at least beneath the contact pad PD and possibly at this contact pad PD.

These structural defects may include cracks and/or delaminations.

The aforementioned detection system MDET is configured to detect the possible presence of at least one type of structural defects DFT within at least one area ZD of the interconnection portion INT, this area ZD being located at least beneath a contact pad PD and which could incorporate the contact pad itself.

As illustrated in FIG. 1, the detection system MDET comprises an electrically-conductive region RGC located in the area ZD at least beneath a contact pad, this electrically-conductive region RGC could also incorporate the contact pad itself as will be seen in more detail hereinafter.

The detection system MDET also includes a detection device configured to detect at least one electrical discontinuity of the region RGC.

In the example of FIG. 1, the detection device may comprise the processing unit UT.

It will be seen hereinafter that the detection system may also include a module external to the integrated circuit, for example a tester.

FIG. 10 schematically illustrates steps of a mode of implementation of a method according to an embodiment.

More particularly, in a step S10, an integrated circuit IC is provided including a semiconductor substrate, and an interconnection portion located above the substrate and having metal levels and vias levels embedded in an electrically-insulating region, the interconnection portion also having contact pads located at the last metal level of this interconnection portion.

Then, in a step S11, the possible presence of at least one type of structural defects within at least one area ZD of the interconnection portion is detected, the area being located at least beneath a contact pad.

More particularly, this detection S11 comprises detecting S110 at least one electrical discontinuity of an electrically-conductive region RGC located in the area ZD.

If such an electrical discontinuity is detected in step S110, then one could conclude on the presence of a defect DFT in the area ZD.

Conversely, if in step S110, no electrical discontinuity of the region RG is detected, then one could conclude that no defect is detected in this area ZD;

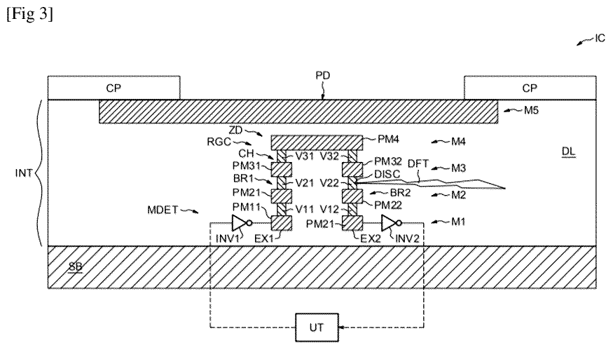

Reference is not made more particularly to FIG. 3 to describe an embodiment.

In this embodiment, the interconnection portion INT includes N=5 metal levels, the rank 1 metal level referenced M1, being the metal level the closest to the substrate SB.

The contact pads PD are located at the rank N metal level, referenced M5.

The metal levels M2, M3 and M4 are intermediate metal levels between the metal level M1 and the metal level M5.

The electrically-conductive region RGC includes an electrically-conductive track CH.

This electrically-conductive track CH has a first end EX1 located at the rank 1 metal level M1 and a second end EX2 also located at the rank 1 metal level M1.

These two ends EX1 and EX2 are able to be electrically coupled to the detection device of the detection system MDET.

In this embodiment, this detection device includes a first inverter INV1 whose output is connected to the first end EX1, a second inverter INV2 whose input is connected to the second end EX2, and the processing unit UT connected, on the one hand, to the input of the first inverter INV1 and, on the other hand, to the output of the second inverter INV2.

The electrically-conductive track CH also includes a first branch BR1 extending from the first end EX1 up to the rank N−1 metal level, herein the rank 4 metal level M4.

The electrically-conductive track CH also includes a second branch BR2 extending from the rank N−1 metal level M4 up to the second end EX2.

The two branches BR1 and BR2 are mutually connected at the rank N−1 metal level M4.

More specifically, the first branch BR1 includes a stack of metal portions PM11, PM21, PM31, PM4 respectively located at the rank 1 to 4 metal levels M1-M4 and of vias V11, V21, V31 between these metal portions.

The metal portion PM11 forms the first end EX1 of the electrically-conductive track CH.

The second branch BR2 includes a stack of metal portions PM21, PM22, PM32, PM4 respectively located at the metal level M1-M4 and of vias V12, V22, V32 between these metal portions.

The metal portion PM21 forms the second end EX2 of the electrically-conductive track CH.

The metal portion PM4 also forms a connection metal portion connecting the two metal portions PM4 of the two branches located at the metal level M4.

As illustrated in FIG. 3, in this embodiment, it is possible to detect a structural defect DFT, of the cracks and/or delamination type, located between the metal level M1 and the metal level M4 by detecting an electrical discontinuity DISC of the electrically-conductive track CH.

For example, in the example of FIG. 3, the defect DFT causes an electrical discontinuity DISC located at the via V22.

However, this embodiment does not allow detecting defect DFT that would be located between the metal level M4 and the contact pad PD.

In return, this embodiment allows performing a detection of a defect DFT in the area ZD between the metal levels M1 and M4, including these levels M1 and M4, whether during a test of the integrated circuit or even during an application operation of the integrated circuit.

To perform this detection, the processing unit UT delivers, for example, at the input of the inverter INV1 a voltage corresponding to a 1 logic level.

If there is no discontinuity DISC, a 0 logic level is obtained at the output of the inverter INV1, which is found at the input of the inverter INV2. Hence, the logic level is found at the output of the inverter INV2.

If the logic level at the input of the inverter INV1 is shifted, in the absence of any discontinuity, we should find the same logic level at the output of the inverter INV2.

Conversely, if, upon a modification of the logic level at the input of the inverter INV1, we do not find this same modification at the output of the inverter INV2, this means that there is an electrical discontinuity in the electrically-conductive track CH, which is synonymous of the presence of a defect DFT.

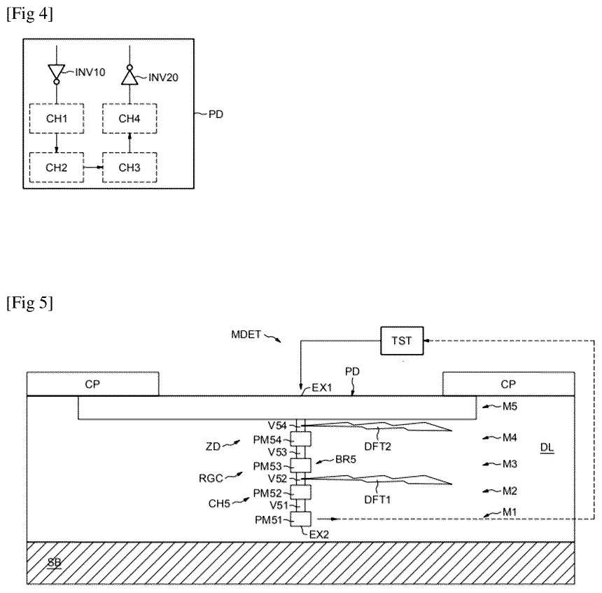

In order to further improve the detection of defects, as schematically illustrated in FIG. 4 which illustrates a top view of the contact pad PD, it is possible to provide within the electrically-conductive region RGC for several star-connected electrically-conductive tracks, herein four electrically-conductive tracks CH1-CH4.

In this schematic figure, these tracks are illustrated at random positions of the contact pad.

In practice, they may, for example, be arranged respectively beneath the four corners of the contact pads PD.

A first inverter INV10 has its output connected to the first end of the track CH1 and a second inverter INV20 has its input connected to the second end of the track CH4.

These two inverters are connected to the processing unit UT in a way similar to what has been described with reference to FIG. 3.

It is then possible to detect one or more discontinuit(y/ies) in one or more of the tracks CH1-CH4.

Of course, it is possible to provide for more than four tracks.

Thus, a fifth track could also be arranged beneath the center of the contact pad.

Reference is now made more particularly to FIG. 5 to describe another embodiment.

In this embodiment, the area ZD in which it is possible to detect any structural defects also incorporates the contact pad PD located at the rank N metal level, herein the metal level M5.

More specifically, it is possible, for example, to detect a defect DFT1 located between the metal level M2 and M3 or a defect DFT2 located between the metal level M4 and the metal level M5 or still possibly a structural defect in the contact pad itself.

In this respect, herein again, the electrically-conductive region RGC includes an electrically-conductive track CH5.

This track CH5 has a first end EX1 located at the contact pad PD and a second end EX2 located at the rank 1 metal level M1. Herein again, the two ends EX1 and EX2 are able to be electrically coupled to the detection device which, in this embodiment, includes an external module such as a tester, TST.

The tester is looped back between the first end EX1 and the second end EX2, for example via another contact pad which is not shown herein.

For example, the tester may apply a voltage difference between the two ends EX1 and EX2 and verify the presence, or not, of a current flowing between these two ends EX1 and EX2.

The presence of a current is synonymous of an absence of electrical discontinuity of the track CH5 and therefore an absence of detection of a defect DFT1 or DFT2.

Conversely, the absence of a current between these two ends is synonymous of the presence of at least one electrical discontinuity of this track and therefore the presence of at least one defect DFT1 or DFT2.

In this respect, the track CH5 includes a branch BR5 extending between the first end EX1 and the second end EX2.

This branch includes a stack of metal portions PM51, PM52, PM53, PM54 respectively located at the metal level M1-M4, of vias V51, V52, V53 between these metal portions and a via V54 between the metal portion PM54 located at the metal level M4 and the contact pad PD.

A defect(s) detection is performed during a test of the integrated circuit but is not be performed during the application operation of the integrated circuit.

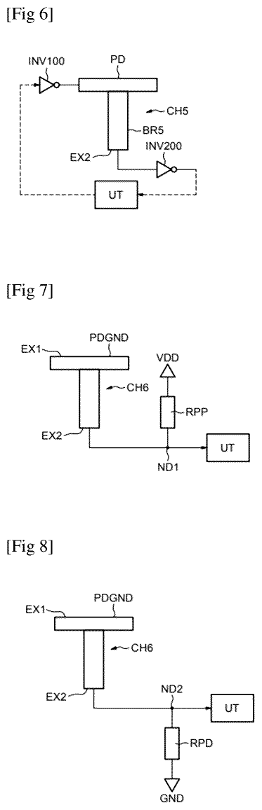

As illustrated in FIG. 6, herein again, to detect the possible presence of a defect, it is possible to use, instead of an external tester TST, the processing unit UT present within the integrated circuit in combination with two inverters INV100 and INV200.

The inverter INV100 has its output connected to the contact pad PD and its input is connected to the processing unit UT.

The second inverter INV200 has its input connected to the second end EX2 of the track CH5 and its output connected to the processing unit UT.

By analogy with what has been described with reference to FIG. 3, a detection of a logic level chattering at the output of the second inverter INV200 in response to a logic level chattering at the input of the inverter INV100 is synonymous of the absence of any electrical discontinuity in the track CH5 and therefore of the absence of detection of a defect.

Conversely, failure to detect a logic level chattering at the output of the second inverter INV200 in response to a chattering at the input of the inverter INV100 is synonymous of at least one electrical discontinuity in the track CH5 and therefore of the presence of at least one structural defect in the area ZD.

When using the processing unit UT for the detection of the electrical discontinuity, the latter should be powered between the supply voltage VDD and the ground GND.

However, it is possible to also detect a defect DFT beneath a contact pad PDGND intended to be connected to the ground by placing, as illustrated in FIG. 7, a pull-up resistor RPP (Pull-up) connected, on the one hand, to the supply voltage VDD and, on the other hand, to the second end EX2 of the electrically-conductive track CH6 a first end of which is located at the contact pad PDGND.

Indeed, in the absence of any electrical discontinuity of the track CH6, the node ND1 connected at the second end EX2 of the track CH6, remains grounded which enables the processing unit to detect an absence of defects.

Conversely, in the presence of at least one electrical discontinuity of the track CH6, the node ND1 is floating but will be pulled towards the supply VDD via the resistor RPP.

An increase in the voltage at the node ND1, detected by the processing unit UT, is then synonymous of an electrical discontinuity in the track CH6 and therefore of the presence of a defect.

In the case where the processing unit UT is intended to detect the possible presence of a defect beneath a contact pad PDVDD intended to be powered with the supply voltage VDD, then it is provided, as illustrated in FIG. 8, to connect a pull-down resistor (pull-down) RPD between the node ND2 connected to the second end EX2 of the track CH7 and the ground GND.

In the absence of any electrical discontinuity of the track CH7, the voltage VDD is present at the node ND2 whereas in the presence of an electrical discontinuity in the track CH7, the voltage at the node ND2 will be grounded via the resistor RPD.

This voltage decrease, detected by the processing unit UT is also synonymous of the presence of at least one electrical discontinuity of the track CH7 and therefore of the presence of at least one structural defect beneath the contact pad PD VDD.

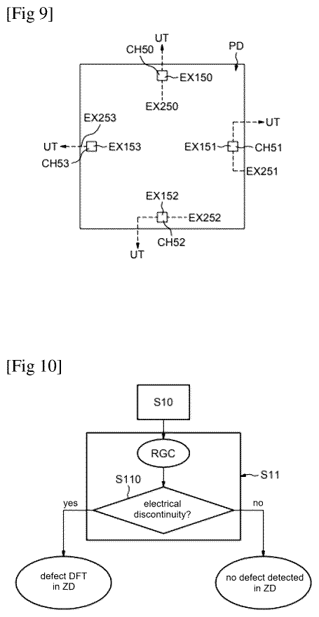

As illustrated in FIG. 9, in order to further improve the defect detection, it is also possible to provide for several star-connected electrically-conductive tracks, herein four tracks CH50, CH51, CH52, CH53, beneath the contact pad PD.

More specifically, the contact pad PD forms the respective first ends EX150, EX151, EX152, EX153 of the four tracks CH50, CH51, CH52, CH53.

The respective second ends EX250, EX251, EX252 and EX253 of these tracks are connected separately, for example at four input ports of the processing unit UT or in a multiplexed manner at one input port of the processing unit.

In the example described herein, the four tracks are connected at the middle of the four edges of the contact pad PD.

Of course, they could be located differently for example at the four corners.

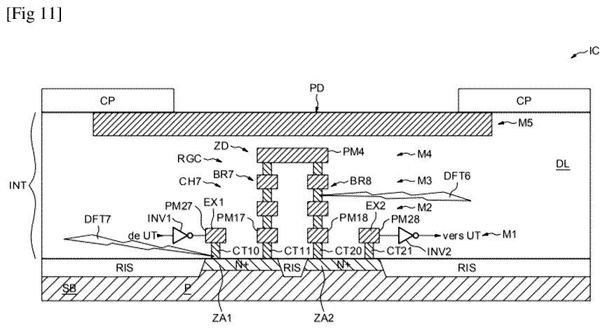

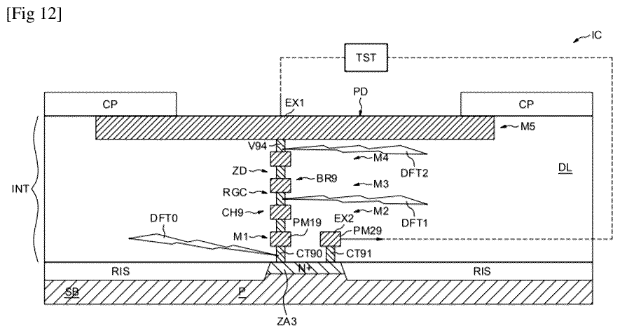

Other embodiments are also possible as it will be now described with reference to FIGS. 11 and 12.

In FIG. 11, elements that are similar or having functions that are similar to those of FIG. 3 bear the same references as those of FIG. 3.

Only the differences between these two figures are described.

The electrically-conductive region RGC includes a first active area ZA1 and a second active area ZA2 located in the semiconductor substrate SB.

The substrate herein typically is a substrate with a P conductivity type and the active areas herein are N⁺ doped areas. They are isolated from each other and isolated from the rest of the substrate SB by insulating regions RIS for example of the “shallow trench” type.

The region RGC also includes an electrically-conductive track CH7.

This electrically-conductive track CH7 has a first end EX1 and a second end EX2 located at the rank 1 metal level and able to be electrically coupled to the detection device, including, like in FIG. 3, inverters INV1 and INV2 connected to the processing unit UT.

The first end of the track CH7 is herein formed by a metal portion PM27.

The second end of the track CH7 is herein formed by another metal portion PM28.

The track CH7 also has a first contact CT10 connected between the first end EX1 (metal portion PM27) and the first active area ZA1.

The track CH7 also includes a first branch BR7 extending from the first active area ZA1 up to the rank N−1 metal level M4 (N=5 herein), and a second branch BR8 extending from the rank N−1 metal level M4 up to the second active area ZA2.

The electrically-conductive track CH7 also includes a second contact CT21 connected between the second active area ZA2 and the second end EX2 (metal portion PM28).

Each branch BR7, BR8 herein includes a stack of metal portions, respectively located at the rank 1 to N−1 metal levels M1 to M4, of vias between these metal portions and of a contact CT11, CT20 between the corresponding active area ZA1, ZA2 and the corresponding metal portion PM17, PM18 located at the rank 1 metal level M1.

A connection metal portion PM4 located at the rank n−1 metal level connects the two metal portions of the two branches located at the rank N−1 metal level.

Such an embodiment wherein the electrically-conductive track CH7 that does not contact the contact pad but extends up to the active areas ZA1, ZA2 of the substrate, allows, if one wishes so, continuously detecting the apparition of a structural defect DFT6, DFT7 beneath the contact pad, even when the integrated circuit is in its application operation, and that being so between the rank N−1 metal level and the semiconductor substrate. In particular, it is possible to detect a defect DFT7 such as a delamination, the closest to the substrate SB.

In FIG. 12, elements that are similar or having functions that are similar to those of FIG. 5 bear the same references as those of FIG. 5.

Only the differences between these two figures are described.

The electrically-conductive region RGC includes a third active area ZA3 located in the semiconductor substrate SB.

The substrate herein typically is a substrate with a P conductivity type and the active area ZA3 herein is an N⁺ doped area. It is isolated from the rest of the substrate SB by insulating regions RIS for example of the “shallow trench” type.

The region RGC also includes an electrically-conductive track CH9.

This electrically-conductive track CH9 has a first end EX1 located at the contact pad PD and a second end EX2 located at the rank 1 metal level, the two ends being able to be electrically coupled to the detection device TST.

The second end EX2 is herein formed by a metal portion PM29 located at the rank 1 metal level M1.

The track CHP also includes a branch BR9 extending between the first end EX1 and the third active area ZA3.

The track CH9 also includes a third contact CT91 connected between the third active area ZA3 and the second end EX2 (metal portion PM29).

The branch BR9 herein includes a stack of metal portions, respectively located at the rank 1 to N−1 metal levels M1 to M4, of vias between these metal portions, of a via V94 between the metal portion located at the metal level M4 and the contact pad PD and of a contact CT90 between the third active area ZA3 and the metal portion PM19 located at the rank 1 metal level M1.

This other embodiment allows detecting a defect DFT2 located at the contact pad or just beneath or a defect located between this contact pad and the substrate, for example a defect DFT1 located at the middle of the branch BR2 or a defect DFT0 located in the vicinity of the substrate SB.

As the case may be, it is also possible to connect a pull-up resistor or a pull-down resistor on the second end EX2 as described with reference to FIGS. 7 and 8.

Of course, what has been described hereinabove for one single contact pad could apply in practice for all of the contact pads, irrespective of the considered embodiment.

In other words, the detection system MDET may be configured to detect the possible presence of at least one type of structural defects within areas ZD of the interconnection portion respectively located at least beneath each contact pad.

Thus, in this respect, it is provided to arrange electrically-conductive regions RGC respectively at least in each area and to provide for at least one detection device UT, TST configured to detect at least one electrical discontinuity DISC of each region RGC. It should also be noted that the present embodiments are compatible with the embodiments described in the aforementioned French patent application number 2406877, providing for the presence of an annular wall inside, or on either or both sides of, the sealing ring.

What is claimed is:

1. An electronic system comprising:
an integrated circuit, including a semiconductor substrate, an interconnection portion located above the substrate and having metal levels and first vias and contact levels embedded in an electrically-insulating region as well as contact pads located at a last metal level of the interconnection portion; and
a detection system configured to detect a possible presence of at least one type of structural defects within at least one area of the interconnection portion located at least beneath a respective contact pad;
wherein the detection system comprises an electrically-conductive region located at least in the area and a detection device configured to detect at least one electrical discontinuity of the electrically-conductive region;
wherein the interconnection portion includes N metal levels with N greater than or equal to 2, a rank 1 metal level being closest to the substrate, the contact pads being located at a rank N metal level;
wherein the electrically-conductive region includes an electrically-conductive track having at least one branch comprising a stack of metal portions, respectively located at the rank 1 to N−1 metal levels, and of second vias between these metal portions.

2. The electronic system according to claim 1, wherein the detection device is located within the integrated circuit.

3. The electronic system according to claim 1, wherein the detection device includes a module external to the integrated circuit.

4. The electronic system according to claim 1, wherein the electrically-conductive track comprises:
a first end and a second end located at the rank 1 metal level and able to be electrically coupled to the detection device;
a first branch extending from the first end up to a rank N−1 metal level; and
a second branch extending from the rank N−1 metal level up to the second end;
the first and second branches being mutually connected at the rank N−1 metal level.

5. The electronic system according to claim 4, wherein each branch includes:
a respective stack of metal portions, respectively located at the rank 1 to N−1 metal levels, and of the second vias between these metal portions; and
a connection metal portion located at the rank N−1 metal level connecting two metal portions of the first and second branches located at the rank N−1 metal level.

6. The electronic system according to claim 1, wherein the electrically-conductive region includes a first active area and a second active area located in the semiconductor substrate, and the electrically-conductive track comprises:
a first end and a second end located at the rank 1 metal level and able to be electrically coupled to the detection device;
a first contact connected between the first end and the first active area;
a first branch extending from the first active area up to a rank N−1 metal level;
a second branch extending from the rank N−1 metal level up to the second active area; and
a second contact connected between the second active area and the second end;
the first and second branches being mutually connected at the rank N−1 metal level.

7. The electronic system according to claim 6, wherein:
each branch includes a respective stack of metal portions, respectively located at the rank 1 to N−1 metal levels, of the second vias between these metal portions and of a contact between a corresponding active area and a corresponding metal portion located at the rank 1 metal level; and
a connection metal portion located at the rank N−1 metal level connects two metal portions of the first and second branches located at the rank N−1 metal level.

8. The electronic system according to claim 4, wherein the electrically-conductive region includes several electrically-conductive tracks.

9. The electronic system according to claim 8, wherein the electrically-conductive tracks are star-connected.

10. The electronic system according to claim 1, wherein the at least one area also incorporates the respective contact pad.

11. The electronic system according to claim 10, wherein the electrically-conductive track comprises:
a first end located at the respective contact pad and a second end located at the rank 1 metal level, the first and second ends being able to be electrically coupled to the detection device; and
a branch extending between the first end and the second end.

12. The electronic system according to claim 11, wherein the branch includes:
a respective stack of metal portions, respectively located at the rank 1 to N−1 metal levels, of the second vias between these metal portions and of a via between the metal portions located at the N−1 metal level and the contact pad.

13. The electronic system according to claim 10, wherein the electrically-conductive region includes a third active area in the semiconductor substrate, and the electrically-conductive track comprises:
a first end located at the respective contact pad and a second end located at the rank 1 metal level, the first and second ends being able to be electrically coupled to the detection device;
a branch extending between the first end and the third active area; and
a third contact connected between the third active area and the second end.

14. The electronic system according to claim 13, wherein the branch includes:
a respective stack of metal portions, respectively located at the 1 to N−1 rank metal levels, of the second vias between these metal portions, of a via between the metal portion located at the N−1 rank metal level and the contact pad and of a contact between the third active area and the metal portion located at the rank 1 metal level.

15. The electronic system according to claim 11, wherein the detection system includes a pull-up resistor having a first terminal able to be coupled to a supply voltage and a second terminal coupled to the second end of the electrically-conductive track.

16. The electronic system according to claim 11, wherein the detection system includes a pull-down resistor having a first terminal able to be coupled to a power supply ground point and a second terminal coupled to the second end of the electrically-conductive track.

17. The electronic system according to claim 11, wherein the electrically-conductive region includes several star-connected electrically-conductive tracks, the contact pad incorporating the first ends of all tracks.

18. The electronic system according to claim 1, wherein the detection system is configured to detect a presence of at least one type of structural defects within areas of the interconnection portion respectively located at least beneath each contact pad.

19. The electronic system according to claim 18, wherein the detection system comprises a plurality of electrically-conductive regions respectively located at least in each area, and the detection device is configured to detect at least one electrical discontinuity of each region.

20. The electronic system according to claim 1, wherein the at least one type of structural defects includes a crack and/or a delamination.

21. A method, comprising:
providing an integrated circuit, including a semiconductor substrate, an interconnection portion located above the substrate and having metal levels, vias and contacts levels embedded in an electrically-insulating region as well as contact pads located at a last metal level of the interconnection portion; and
detecting a possible presence of at least one type of structural defects within at least one area of the interconnection portion located at least beneath a respective contact pad.

22. The method according to claim 21, wherein the detecting comprises detecting at least one electrical discontinuity of an electrically-conductive region located at least in the area.

23. The method according to claim 21, wherein the area also incorporates the respective contact pad.

24. The method according to claim 22, wherein the electrically-conductive region includes at least one active area located in the semiconductor substrate.

25. The method according to claim 21, wherein the at least one type of structural defects includes a crack and/or a delamination.
